(19) United States
(12) Patent Application Publication
(10) Pub. No.: US 2024/0336519 A1
(43) Pub. Date: Oct. 10, 2024

(54) SUBSTRATE AND PACKAGE SUBSTRATE COMPRISING THE SAME

(71) Applicant: Absolics Inc., Covington, GA (US)

(72) Inventors: Sungjin KIM, Covington, GA (US); Jincheol KIM, Hwaseong-si (KR)

(73) Assignee: Absolics Inc., Covington, GA (US)

(21) Appl. No.: 18/575,061

(22) PCT Filed: Aug. 23, 2022
(86) PCT No.: PCT/US2022/041178

§ 371 Date: Dec. 28, 2023

Related U.S. Application Data
(60) Provisional application No. 63/235,847, filed on Aug. 23, 2021.

(51) Int. Cl. C03C 17/30

(52) U.S. Cl. CPC C03C 17/30; C03C 2217/78; C03C 2218/32

(57) ABSTRACT

A substrate comprising a glass substrate is provided. The glass substrate includes a first surface, a second surface, and an edge area connecting the first surface and the second surface; a groove part formed toward the inside direction of a glass substrate from a portion of the edge area; and a protecting device formed on the groove part, wherein the groove part penetrates the first surface and the second surface.

### CROSS-REFERENCE TO RELATED APPLICATIONS

This application claims the priority of U.S. Provisional Patent Application No. 63/235,847, filed Aug. 23, 2021, the entire disclosures of which are incorporated herein by reference for all purposes.

### BACKGROUND

### 1. Field

The following description relates to a substrate and a package substrate comprising the same.

### 2. Description of Related Art

In a packaging process that applies a glass substrate to large panels implemented in transportation operations, processing, and the like, impact may occur to the glass substrate. This impact may result in problems such as, but not limited to, processing loss, defects, and the like.

The implementation used in a glass substrate transportation, processing, and the like may typically comprise a material with a high stiffness, and may cause defects or cracks in a glass substrate, and it may lead to damage of the whole glass substrate.

Accordingly, a solution that may minimize the occurrence of damages, defects, or cracks in processes such as transportation, processing, and the like of a glass substrate may be beneficial.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a substrate includes a glass substrate comprising a first surface, a second surface, and an edge area configured to connect the first surface and the second surface; and a protecting device, wherein the protecting device is disposed on at least a portion of the edge area, and wherein the protecting device has a minimum thickness of 5 μm or more.

The substrate may include a groove part that penetrates the first surface and the second surface toward an inner portion of the glass substrate, and wherein the protecting device is disposed at the groove part.

At least one of the first surface and the second surface of the glass substrate may be configured to have a shape of quadrangle to octagon, wherein the glass substrate comprises a through via that penetrates from the first surface to the second surface, and wherein the glass substrate comprises at least one of an electrically conductive wire and an electrically conductive layer in at least a portion of the glass substrate.

The protecting device may include a first protecting device and a second protecting device which are distinct from each other, the first protecting device is disposed in an edge area in contact with a first side of the first surface, the second protecting device is disposed in an edge area in contact with a second side of the first surface, and the first side and the second side are disposed to face each other.

The groove part may include a first groove part and a second groove part which are distinct from each other, and wherein the first groove part and the second groove part may be disposed to face each other with the first surface therebetween.

The protecting device may include a polymer layer whose total transmittance is equal to or greater than 87%.

The polymer layer may be an elastic layer, and the protecting device and the glass substrate may be configured to have an adhesive strength of 5 B according to ASTM D3359.

Damage of the glass substate of the substrate may not be substantial when impact with a pressure of approximately 1.1 bar is added three times to the protecting device to be directly contacted with a pin having a section that corresponds with a section of the groove part.

Damage of the glass substrate of the substrate may not be substantial when impact with a pressure of approximately 1.1 bar is added fifty times to the protecting device to be directly contacted with a pin having a section that corresponds with a section of the groove part.

The groove part may have a shape that corresponds to any one of a circle, and an oval, and a distance from a first point of the groove part to the edge area may be 1 mm to 15 mm.

The protecting device may be configured to have a pencil hardness of HB or greater according to ASTM D3363.

The polymer layer may include an ultraviolet (UV) cured resin.

The glass substrate may include a cavity unit disposed in a portion of the glass substrate, and a thickness between a first surface of the cavity unit and a second surface of the cavity unit may be thinner than a thickness between the first surface of the glass substrate and the second surface of the glass substrate.

The glass substrate may include an upper redistribution layer on the first surface, and a lower redistribution layer under the second surface.

A semiconductor substrate includes the substrate according to claim 1, and a semiconductor element mounted on the substrate.

Other features and aspects will be apparent from the following detailed description, the drawings, and the claims.

### BRIEF DESCRIPTION OF DRAWINGS

FIG. 1 illustrates a ground plan of an example substrate, in accordance with one or more embodiments.

FIG. 2 illustrates a perspective drawing of an example glass substrate, in accordance with one or more embodiments.

FIG. 3 illustrates a perspective drawing of an example substrate, in accordance with one or more embodiments.

FIG. 4 illustrates a perspective drawing of an example glass substrate, in accordance with one or more embodiments.

FIG. 5 illustrates a front view of an example glass substrate, in accordance with one or more embodiments.;

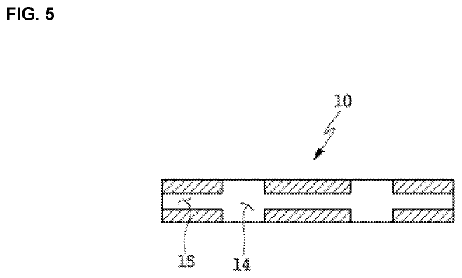

FIG. 6 illustrates a ground plan of an example substrate, in accordance with one or more embodiments.

FIG. 7 illustrates a picture of a state of an example glass substrate of Comparative Examples of a test after three times of impact for a groove part, in accordance with one or more embodiments.

FIG. 8 illustrates a picture of a state of an example substrate of Examples of a test after fifty times of impact for a groove part, in accordance with one or more embodiments.

FIG. 9 illustrates a picture of a state of adhesion between a polydimethylsiloxane (PDMS) protecting device and a groove part of a substrate of one or more Examples.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which this disclosure pertains consistent with and after an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

In this application, terms such as “first,” “second,” “A,” or “B” are used to distinguish the same terms from each other.

In this application, a singular form is contextually interpreted as including a plural form as well as a singular form unless specially stated otherwise.

One or more examples may provide a substrate which can prevent occurring impact or damage in processes such as transportation, processing, and the like of glass substrate at a packaging process.

In one or more examples, a protecting device may be equipped in a substrate and thereby excessive impact may be prevented from being applied inside a glass substrate during transportation, processing, and the like of a packaging process.

### Substrate 100

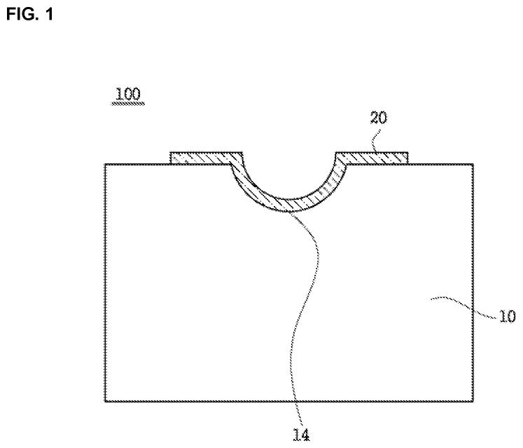

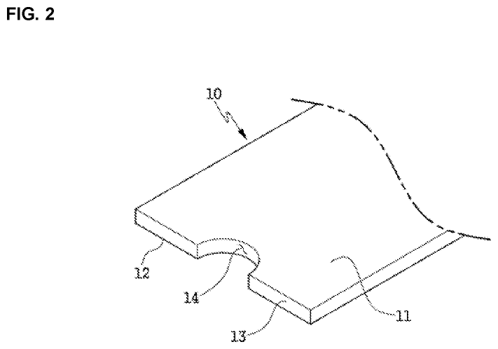

Referring to FIGS. 1 and 2, in one or more examples, a substrate 100 may include a glass substrate 10 comprising a first surface 11, a second surface 12, and an edge area 13 connecting the first surface 11 and the second surface 12; and a protecting device 20. In a non-limited example, the protecting device 20 may be disposed on at least a portion of the edge area 13, and, in an example, the protecting device 20 may comprise a polymer layer whose total transmittance is about 87% or more.

The glass substrate 10 may further comprise a groove part 14 that protrudes toward an inner portion of the glass substrate 10. The groove part 14 may penetrate the first surface 11 and the second surface 12, and the groove part 14 may be disposed in at least a portion of the edge area 13, and may be connected to the edge area 13. In a non-limited example, the protecting device 20 may be disposed on the groove part 14.

In a non-limited example, the glass substrate 10 may have a shape of a quadrangle to octagon, or a square shape when the first surface 11, except the groove part 14, is viewed in an upper position. The glass substrate 10 may have four sides and four edge areas.

In an example, the protecting device 20 may comprise a first protecting device and a second protecting device which are distinct from each other, and may be disposed spatially separate from each other. The first protecting device may be disposed in an edge area in contact with a first side of the first surface 11, the second protecting device may be disposed in an edge area in contact with a second side of the first surface 11, and the first side and the second side may face each other.

The groove part 14 may comprise a first groove part and a second groove part which are distinct from each other. The first groove part and the second groove part may be disposed to face each other, having the first surface 11 or the second surface 12 therebetween.

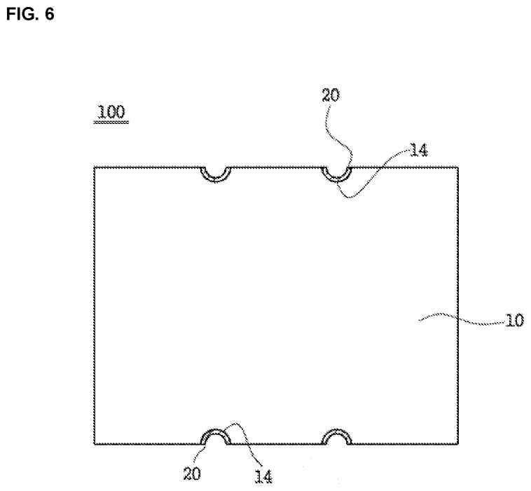

The groove part 14 and the protecting device 20 formed on the groove part 14 may be comprised in a first edge area of the glass substrate 10 and a second edge area opposite to the first edge area, as illustrated in FIG. 6. The groove part and the protecting device may be formed in a plural number, and may be formed in a number of 1 to 10 based on one edge area of a glass substrate.

The substrate 100 may have a protecting device 20 formed to be extended in any one or more areas among an edge area of the glass substrate 10 connected to the groove part 14, a first surface 11 connected to the groove part 14, and a second surface 12 connected to the groove part 14, and the protecting device 20 may be extended by 10 μm to 500 μm. As illustrated in FIG. 1, the protecting device 20 may also be formed to be extended in an edge area except for the groove part 14.

The groove part 14 may have a shape that is concaved by a predetermined length to the center direction of the first surface 11 or the second surface 12 from the edge area 13, as illustrated in FIG. 2. The protecting device 20 may be formed on the inner circumference surface of the groove part. The groove part 14 may have a maximum concaved length of 2.5 mm or less, 1 mm or less, or 0.8 mm or less. The groove part may have a concaved length of 0.2 mm or more. The substrate 100 may have such a concaved length and thereby may obtain convenience in transportation and processing through a transporting device in contact with the groove part.

The groove part 14 may have substantially the same grooves in the first surface 11 and the second surface 12, and may have a penetrated shape. The section of the groove part 14 may be a cut circle shape or a cut oval shape, may comprise a circumference and an arc of an oval or a circle, or may comprise a curve, when a first surface 11 of the glass substrate 10 is viewed in an upper position, or when the second surface 12 is viewed in a lower position. Additionally, the distance from at least one point of the groove part to the edge area may be 1 mm to 15 mm.

The section of the groove part 14 may comprise a circumference and an arc of a circle or a half circle shape with a diameter of 1 mm to 5 mm. A protecting device 20 can be more stably formed by having such a shape, and impact added through a transporting device and the like can be minimized.

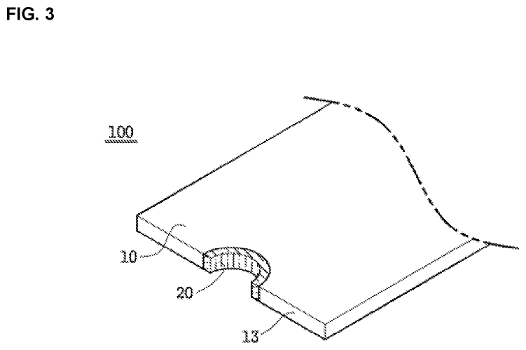

The protecting device 20 may be formed on, or in, the groove part 14 to be in contact with the groove part 14 as illustrated in FIG. 3, and may have a substantially same shape along the circumference of the groove part 14.

In an example, the protecting device 20 may have a thickness of 5 μm as the minimum or more, 10 μm to 1000 μm, 50 μm to 1000 μm, or 100 μm to 400 μm based on the external direction perpendicular to the thickness of a glass substrate 10 from an edge area 13 of the glass substrate 10. The protecting device 20 may minimize impact added through a transporting device and the like by having such a thickness.

The protecting device 20 may be formed by applying a raw material composition evenly to the groove part 14, and through ultraviolet (UV) irradiation and/or thermal treatment. In an example, the raw material composition may comprise a monomer, an oligomer or a prepolymer based on siloxane, acetate, acetal, urethane, or amide, and may comprise a curing agent, a curing catalyst, a photoinitiator, a solvent, and the like. As the siloxane-based prepolymer, polydimethylsiloxane, polydiphenylsiloxane, polyphenylmethylsiloxane, or the like may be comprised. A compound based on isocyanate or amine may be implemented as the curing agent. The raw material composition may comprise a reinforcing agent, an adhesion enhancer, a chain extender, and the like as needed.

The raw material composition may be a first composition comprising a polydimethylsiloxane prepolymer, a curing agent, and a curing catalyst, or may be a second composition in which a composition comprising a polydimethylsiloxane prepolymer and a curing catalyst and a composition comprising a polydimethylsiloxane prepolymer, a curing catalyst, and other additives are mixed in a predetermined ratio.

A polymer layer of the protecting device 20 may be a layer having elasticity, may comprise a polymer resin treated by UV curing, and may comprise a polymer resin having acid resistance and heat resistance. In an example, the polymer resin may comprise a siloxane-based polymer, polyvinyl acetate, polyvinyl acetal, polyvinyl butyral, polyurethane, polyether block amide and the like. As the siloxane-based polymer, polydimethylsiloxane, polydiphenylsiloxane, polyphenylmethylsiloxane, and the like may be comprised. The polyvinyl acetate may be one having vinylacetate in an amount of 20 wt % to 50 wt %. The polyvinyl butyral may be soft one comprising a plasticizer. The polyurethane may be a thermal curable, thermal plastic, and foaming polyurethane.

An adhesive strength between the protecting device 20 and a groove part 14 of the glass substrate 10 may be 5 B based on a standard according to ASTM D3359. The 5 B substantially means a delaminated area is not generated when an adhesion test according to the ASTM D3359 is performed. Additionally, the protecting device 20 may have a pencil hardness of HB or above, or H or below according to ASTM D3363. The protecting device 20 may have these adhesive strength and hardness, and thereby delamination of the protecting device 20 may be effectively prevented, and a glass substrate 10 can be protected stably when a substrate 100 is transported.

The protecting device 20 may have an elastic modulus of 0.5 MPa to 4 MPa, or 1.8 MPa to 4 MPa.

The protecting device 20 may have a thermal conductivity of 0.1 W/mK to 0.37 W/mK.

The protecting device 20 may have a dielectric strength of 14 kV/mm to 24 kV/mm.

The protecting device 20 may have a dielectric constant of 2 to 4 at 100 kHz.

The protecting device 20 may have a coefficient of thermal expansion of 220 ppm/° C. to 460 ppm/° C.

The protecting device 20 may have a tensile strength of 5.5 MPa to 7.9 MPa.

The protecting device 20 may have a total transmittance of 87% or more, or 89% or more with respect to a visible light based on a thickness of 20 μm. The total transmittance may be 95% or less. The protecting device 20 may have such a total transmittance, and thereby may prevent a problem such as interference occurrence caused from addition of a protecting device.

The substrate 100 may not incur substantial damage to the glass substrate 10 during the admission of a damage test that adds a pressure of 1.1 bar for one second to the protecting device 20 which is in contact with a pin having a section that corresponds with a section of the groove part 14, when the damage test is performed three times to ten times. The substrate 100 may not have substantial damage to the glass substrate even after the damage test is performed at least fifty times, and may not generate a break thereof. The degree of damage and break refers to a state of not generating a crack or a split when the glass substrate is observed with a naked eye. A substrate having such a characteristic may minimize impact which might be incurred during transportation and processing through a transporting device like a pin and prevent a break and the like.

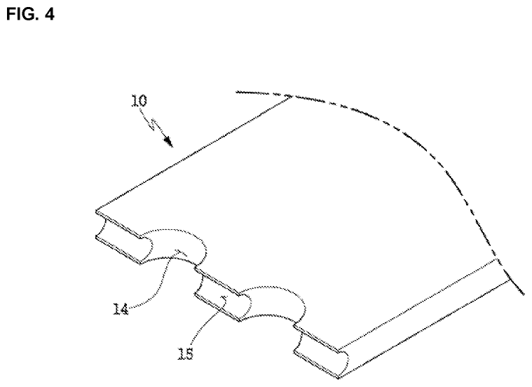

Referring to FIG. 4, the substrate 100 may further comprise a third groove part 15 formed along the circumference of the edge area in an edge area except for the groove part 14, and may further comprise a third protecting device (not shown) formed on the third groove part. In an example, the third groove part may have a shape concaved to the center direction of the one surface 11 or the other surface 12 in an edge area excepting for the groove part.

The glass substrate 10 may have a shortened wiring length between an element and a printing circuit substrate when applied as a substrate for packaging.

Glass applicable as the glass substrate 10 may include a tempered glass, borosilicate glass, non-alkali glass and the like, as non-limited examples. The glass substrate 10 may not substantially comprise an organic substrate.

A separate adhesive and the like substantially may be not comprised between the glass substrate 10 and the protecting device 20.

The glass substrate 10 may have a thickness of 2000 μm or less, 100 μm to 1500 μm, or 100 μm to 1000 μm. A glass substate having such a thickness can further enhance efficiency of electrical signal transmission, and can maintain proper mechanical properties in a state of disposing the protecting device 20.

The glass substrate 10 may further comprise plural vias having some routes formed in a thickness direction and other vias having routes formed in a direction substantially perpendicular to the thickness direction.

The glass substrate 10 may comprise a through via that penetrates from the first surface 11 to the second surface 12.

The glass substrate 10 may comprise an electrically conductive wire or an electrically conductive layer disposed in at least a portion of the glass substrate 10, and may comprise an electrically conductive layer which electrically connects the first surface 11 and the second surface 12 through a core via, a via, and the like.

The first surface 11 and/or the second surface 12 of the glass substrate 10 may

comprise a circuit pattern, and an opposite surface of a surface where an element is placed may be electrically connected to a printing circuit substrate by using an electrical connecting device such as a lead frame, a solder ball, and the like as a medium.

The glass substrate 10 may include a separately prepared cavity device, and the cavity device may be disposed to be an empty space inside the glass substrate.

A passive element may be disposed in the inside of the glass substrate 10, and the passive element may be disposed and placed in a cavity inside the glass substrate 10.

The substrate 100 may include an upper redistribution layer on the one surface 11, and may comprise a lower redistribution layer under the other surface 12.

The substrate 100 may have a groove part 14 and a protecting device 20 disposed throughout an edge area 13, a first surface 11, and a second surface 12, and may thereby reinforce durability of the edge which is relatively weak during processes such as transportation and processing in a packaging process and may further increase productivity.

### Package Substrate

In an example, a package substrate, in accordance with one or more embodiments may include a substrate 100 according to the above; and an element disposed on one surface 11 of the substrate.

The package substrate may further include a lead frame that protects the element from external environments, and assists in a heat emission process on the first surface 11 thereof. A thermal conductive filling material may be filled between the element and the lead frame, and the adhesive surface between the element and the lead frame may be treated by soldering.

### Manufacturing Method for Substrate

In one or more examples, a manufacturing method for a substrate according to example embodiments may include an operation of preparing a glass substrate comprising a first surface, a second surface, and an edge area connecting the first surface and the second surface, and forming a groove part toward the inside direction of a glass substrate from some of the edge area; and an operation of applying a raw material composition on the groove part for curing treatment thereof.

The operation of forming the groove part 14 may form the groove part 14 to penetrate the first surface and the second surface, and the groove part may be formed through a cutting processing, a laser processing, a chemical etching after the laser processing, and the like.

The detailed shape of the groove part 14 formed through the operation of forming the groove part 14 is the same as the above description of the substrate 100, and thus the overlapped description is omitted.

The curing treatment operation may be performed by applying a raw material composition on the groove part to be a predetermined thickness and subsequently operating thermal treatment and/or UV irradiation.

In the curing treatment operation, the raw material may have a viscosity of 10000 cPs or less, or 1000 cPs or more, and preferably may have a viscosity of 2000 cPs to 5000 cPs. Any viscosity range to easily penetrate the internal area of a packaging and without generating pollution can be applied thereto.

A material which may be included in the raw material of the curing treatment operation is the same as the above description of the substrate, and thus the overlapped description is omitted.

The thermal treatment of the curing treatment operation may proceed at a temperature of 20° C. to 180° C. The thermal treatment may proceed for 5 minutes to 30 minutes at a temperature of 150° C. to 180° C., or may proceed for 10 minutes to 50 minutes at a temperature of 100° C. to 150° C.

The UV irradiation of the curing treatment operation may be performed by UV having a wavelength range of 320 nm to 380 nm at an energy density of 800 mJ/mm² to 1400 mJ/mm², or at an energy density of 1000 mJ/mm² to 1200 mJ/mm². When photocuring treatment is performed under such a condition, a protecting device with good adhesive strength and properties can be formed.

The UV irradiation of the curing treatment operation may proceed for 10 seconds or more, or 3 minutes or less, and preferably may proceed for 20 seconds to one minute, but the condition is not necessarily limited thereto. Additionally, an additive UV irradiation may proceed after the thermal treatment. Through such a UV irradiation, the occurrence of dust or impurities after curing can be minimized. Additionally, when a material weak in UV resistance is comprised in a semiconductor packaging process, the UV irradiation may be excepted from the process.

Hereinafter, while examples will be described in more detail with reference to the accompanying examples, it is noted that examples are not limited to the same.

### EXAMPLE—SUBSTRATE

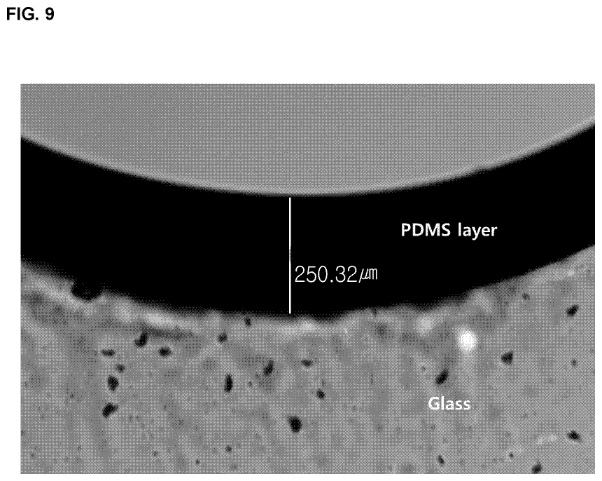

A quadrangle glass substrate 10 having a thickness of 500 μm was prepared. A groove part 14 having a half circle shaped section with a diameter of 1.5 mm was formed by etching through laser in a first edge of the glass substrate and a second edge opposite thereto as illustrated in FIG. 6. SYLGARD 184 available from DOW CHEMICAL as a raw material composition comprising a polydimethylsiloxane prepolymer with a viscosity of 3500 cPs or less was evenly applied to be a thickness of 270 μm on the groove part, and thermal treatment thereof was performed for 10 minutes at a temperature of 150° C. Thereafter, UV having a wavelength of 350 nm and an energy density of 1100 mJ/mm² was irradiated to the applied portion for one minute to be treated by photocuring, and a protecting device 20 comprising polydimethylsiloxane (PDMS) was formed as illustrated in FIG. 9.

### Comparative Example—Substrate without Protecting Device

A glass substrate except for a protecting device 20 from the above Example was prepared.

### Experimental Example—Impact Test for Groove Part

A damage test was performed by adding a pressure of 1.1 bar for one second to groove parts of a glass substrate 100 prepared in the Example and a glass substrate prepared in Comparative Example with a stainless pin having the same section as the groove parts and a diameter of 1.5 mm to be in contact with the groove parts.

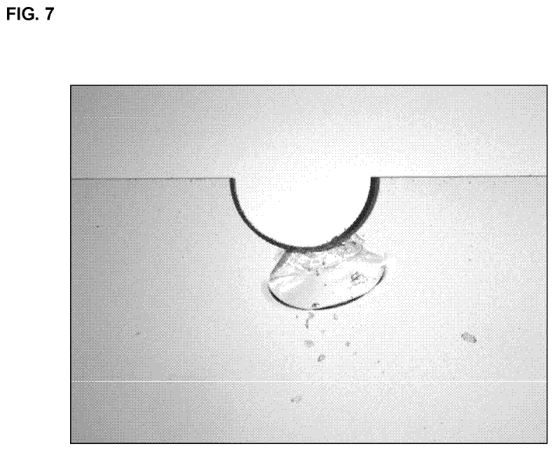

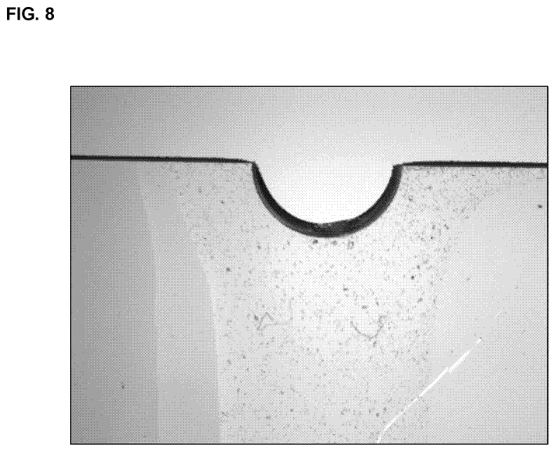

In an Example equipped with a protecting device 20 on a groove part 14, it was verified that damage may not occur even after the damage test performed fifty times as illustrated in FIG. 8. In a Comparative Example without a protecting device, it was verified that a crack occurs around a groove part after the damage test performed three times as illustrated in FIG. 7.

### Experimental Example—Tests for Adhesive Strength, Hardness, and Transmittance of Protecting Device of Substrate

An adhesive strength of a protecting device of a glass substrate 10 to prevent impact prepared in the Example was measured through a coating system to measure adhesive strength available from KTA-TATOR according to ASTM D3359-97 as follows: A first surface of a protecting device was lined to have six lines in the breadth and six lines in the length with intervals of 2 mm, thereby forming a lattice, a testing tape was attached on this lattice, and after that the testing tape was detached at 180° to verify the degree of delamination of a protecting device from the testing tape. Additionally, a pencil hardness of a protecting device of the glass substrate to prevent impact was measured through Pencil Hardness Tester available from KIPAE E&T and Pressure-Proofed Hi-Density Lead Pencil available from MITSUBISHI.

Specifically, a protecting device was fixed on a glass substrate of Pencil Hardness Tester toward the upper direction, a Mitsubishi pencil was installed to make an angle of 45° with a surface of a protecting device, and after that the hardness was judged depending on whether a scratch was generated or not generated when the surface of the protecting device was scratched five times in a state of being added 1 kgf. In an example, a pencil hardness value when a scratch was not generated was taken as a tested value, and a total transmittance of a visible ray of a protecting device was measured.

As the measured result, it was verified that an adhesive strength between the protecting device and the glass substrate was 5 B (not generating any loss), a pencil hardness of the protecting device was HB, and a total transmittance of the protecting device was 89%.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A substrate, comprising:
a glass substrate comprising a first surface, a second surface, and an edge area configured to connect the first surface and the second surface; and
a protecting device,
wherein the protecting device is disposed on at least a portion of the edge area, and
wherein the protecting device has a minimum thickness of 5 μm or more.

2. The substrate of claim 1, further comprising:
a groove part that penetrates the first surface and the second surface toward an inner portion of the glass substrate, and
wherein the protecting device is disposed at the groove part.

3. The substrate of claim 1, wherein at least one of the first surface and the second surface of the glass substrate is configured to have a shape of quadrangle to octagon,
wherein the glass substrate comprises a through via that penetrates from the first surface to the second surface, and
wherein the glass substrate comprises at least one of an electrically conductive wire and an electrically conductive layer in at least a portion of the glass substrate.

4. The substrate of claim 1, wherein:
the protecting device comprises a first protecting device and a second protecting device which are distinct from each other,
the first protecting device is disposed in an edge area in contact with a first side of the first surface,
the second protecting device is disposed in an edge area in contact with a second side of the first surface, and
the first side and the second side are disposed to face each other.

5. The substrate of claim 2, wherein the groove part comprises a first groove part and a second groove part which are distinct from each other, and
wherein the first groove part and the second groove part are disposed to face each other with the first surface therebetween.

6. The substrate of claim 1, wherein the protecting device comprises a polymer layer whose total transmittance is equal to or greater than 87%.

7. The substrate of claim 6, wherein the polymer layer is an elastic layer, and wherein the protecting device and the glass substrate are configured to have an adhesive strength of 5 B according to ASTM D3359.

8. The substrate of claim 2, wherein damage of the glass substate of the substrate is not substantial when impact with a pressure of approximately 1.1 bar is added three times to the protecting device to be directly contacted with a pin having a section that corresponds with a section of the groove part.

9. The substrate of claim 2, wherein damage of the glass substrate of the substrate is not substantial when impact with a pressure of approximately 1.1 bar is added fifty times to the protecting device to be directly contacted with a pin having a section that corresponds with a section of the groove part.

10. The substrate of claim 2, wherein the groove part has a shape that corresponds to any one of a circle, and an oval, and
wherein a distance from a first point of the groove part to the edge area is 1 mm to 15 mm.

11. The substrate of claim 2, wherein the protecting device is configured to have a pencil hardness of HB or greater according to ASTM D3363.

12. The substrate of claim 6, wherein the polymer layer comprises an ultraviolet (UV) cured resin.

13. The substrate of claim 1, wherein the glass substrate comprises a cavity unit disposed in a portion of the glass substrate, and
wherein a thickness between a first surface of the cavity unit and a second surface of the cavity unit is thinner than a thickness between the first surface of the glass substrate and the second surface of the glass substrate.

14. The substrate of claim 1, wherein the glass substrate comprises an upper redistribution layer on the first surface, and
a lower redistribution layer under the second surface.

15. A semiconductor substrate, comprising:
the substrate according to claim 1, and
a semiconductor element mounted on the substrate.
